(19) United States
(12) Patent Application Publication
(10) Pub. No.: US 2010/0142173 A1
(43) Pub. Date: Jun. 10, 2010

(54) Signal filter module

(75) Inventor: Po-Jung Chen, Taoyuan City (TW)

Correspondence Address: BACON & THOMAS, PLLC, 625 SLATERS LANE, FOURTH FLOOR, ALEXANDRIA, VA, 22314-1176, US

(73) Assignee: U.D.ELECTRONIC CORP., Taoyuan City (TW)

(21) Appl. No.: 12/461,835

(22) Filed: Aug. 26, 2009

(30) Foreign Application Priority Data
Dec. 8, 2008 (TW) 097221975

(51) Int. Cl. H05K 7/02

(52) U.S. Cl. 361/811

(57) ABSTRACT

A signal filter module includes an electrically insulative housing having protruding blocks respectively protruded from the bottom edge of each of two opposite vertical sidewalls thereof and a wire groove defined between each two adjacent protruding blocks, metal terminals each having a base partially embedded in one of the vertical sidewalls of the electrically insulative housing and partially exposed to the outside of the associating vertical sidewall to provide a bonding surface and a bonding tip extended from one end of the base and suspending outside the electrically insulative housing for bonding to an external circuit board, and filter elements each having coils wound thereon with lead ends of the coils respectively inserted through the wire grooves of the electrically insulative housing and bonded to the bonding surfaces of the bases of the metal terminals.

### BACKGROUND OF THE INVENTION

1. Field of the Invention

The present invention relates to signal filter technology and more particularly, to a signal filter module, which has metal terminals directly embedded in two vertical sidewalls of an electrically insulative housing for the bonding of lead ends of coils of filter elements accommodated in the electrically insulative housing by an automatic soldering machine, simplifying the fabrication and saving the cost.

2. Description of the Related Art

Following development of electronic information products toward fine and delicate design, SMT (Surface Mount Technology) is commonly used for the bonding of electronic components to a circuit board. Further, during signal transmission of a network interface component, for example, RJ-45 connector, it may cause an electromagnetic interference with surrounding electronic components or circuits, or the surrounding noises may interfere with the transmission of signal through the RJ-45 connector, resulting a signal transmission error. The electromagnetic interference may disturb surrounding wireless signal transmission, affecting normal functioning of the local area network. To avoid these problems, a signal filter module is usually used and set in the RJ-45 connector. A signal filter module for this purpose is a chip type module. It can be bonded to a network circuit board or interface card (not limited to RJ-45 connector). After installation of a signal filter module in a network connector, the signal filter module removes noises from the signal being transmitted from an external signal source into the network connector for further transmission to an external control circuit interface or any other of a variety of data transmission interface means. After conversion of a network signal into a series data signal, the signal can then be processed through a data processing system.

FIGS. 7 and 8 show a signal filter module according to the prior art. According to this design, the signal filter module comprises an electrically insulative housing A, a plurality of metal terminals B, a plurality of filter elements C and an electrically insulative top cover D. The metal terminals B are respectively fixedly secured to the two opposite sidewalls A1 of the electrically insulative housing A by insert molding. The metal terminals B extend vertically from the bottom side of the sidewalls A1 to the top side thereof, each having a bonding tip B1 turned perpendicularly out of the bottom side of the electrically insulative housing A and bonded to one respective copper finger E1 of an external circuit board E and a top pin B2 protruding over the topmost edge of the electrically insulative housing A. The filter elements C have lead wires C1 wound round the top pins B2 of the metal terminals B and then soldered thereto. This design of signal filter module has drawbacks as follows:

1. Winding the lead wires C1 of the filter elements C round the top pins B2 of the metal terminals B wastes much time and labor, complicating the operation and increasing the cost.

2. Because the metal terminals B extend through the height of the electrically insulative housing A, they must have a certain length, increasing the material cost.

3. Because the top pins B2 of the metal terminals B protrude over the topmost edge of the electrically insulative housing A for the fastening of the lead wires C1 of the filter elements C, the top cover D is necessary for protection. The use of the top cover D complicates the fabrication and cost of the signal filter module.

Therefore, there is a need to provide a signal filter module that eliminates the drawbacks of the aforesaid prior art design.

### SUMMARY OF THE INVENTION

The present invention has been accomplished under the circumstances in view. It is one object of the present invention to provide a signal filter module, which diminishes terminal material consumption, saving the manufacturing cost. It is another object of the present invention to provide a signal filter module, which simplifies the fabrication and lowers the defective rate. It is still another object of the present invention to provide a signal filter module, which uses one commonly specification of metal terminals to fit different sizes of electrically insulative housings, simplifying inventory control and saving the cost.

To achieve these and other objects of the present invention, a signal filter module comprises an electrically insulative housing, a plurality of metal terminals installed in the electrically insulative housing at two opposite sides, and a plurality of filter elements mounted inside the electrically insulative housing and electrically connected to the metal terminals. The metal terminals are directly embedded in two opposite vertical sidewalls of the electrically insulative housing, each having a base exposed to the outside of the bottom edge of the associating vertical sidewall for the bonding of one lead end of one coil of one filter element and a bonding tip thereof suspending outside the electrically insulative housing for bonding to one respective metal contact of an external circuit board. This design needs not to insert the base of each metal terminal through the front and back sides of the associating vertical sidewall so that the metal terminals can be relatively shortened, diminishing terminal material consumption and saving the cost.

Further, the metal terminals are directly embedded in the vertical sidewalls of the electrically insulative housing that can be configured subject to any of a variety of sizes and specifications to fit different requirements. Therefore, one common specification of metal terminals can be used to fit different sizes of electrically insulative housings, simplifying inventory control and saving the cost.

Further, the electrically insulative housing has a plurality of protruding blocks respectively protruded from the bottom edge of each of the two opposite vertical sidewalls thereof, and a wire groove defined between each two adjacent protruding blocks at each of the two opposite vertical sidewalls. The lead ends of the coils of the filter elements are respectively inserted through the wire grooves of the electrically insulative housing and secured to a respective locating notch on the base of each of the metal terminals for easy bonding to a bonding surface on the base of each of the metal terminals by an automatic soldering machine, lowering the defective rate and simplifying the fabrication.

Further, the metal terminals can be directly embedded in the vertical sidewalls of the electrically insulative housing by means of insert molding, simplifying the fabrication and saving the manufacturing cost.

### BRIEF DESCRIPTION OF THE DRAWINGS

FIG. 1 is an elevational view showing a signal filter module bonded to a circuit board according to a first embodiment of the present invention.

FIG. 2 is an exploded view of the signal filter module in accordance with the first embodiment of the present invention.

FIG. 3 is an oblique bottom elevation of the signal filter module in accordance with the first embodiment of the present invention.

FIG. 4 is a sectional side view in an enlarged scale of FIG. 1.

FIG. 5 is an exploded view of a signal filter module in accordance with a second embodiment of the present invention.

FIG. 6 is a sectional view of the second embodiment of the present invention, showing the signal filter module installed in a circuit board.

FIG. 7 is an exploded view of a signal filter module according to the prior art.

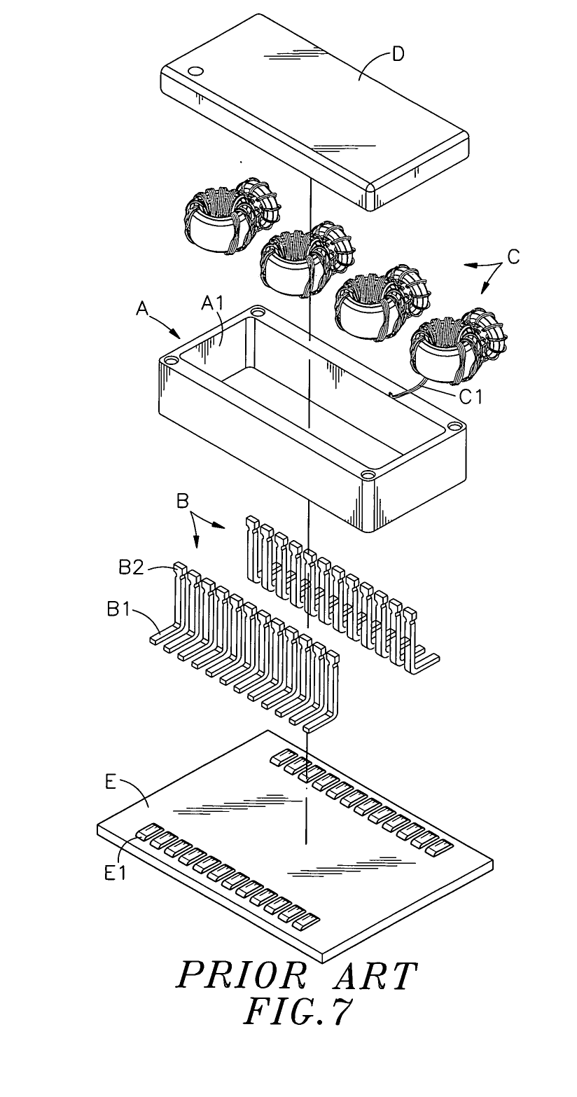

FIG. 8 is a sectional view showing the prior art signal filter module installed in a circuit board.

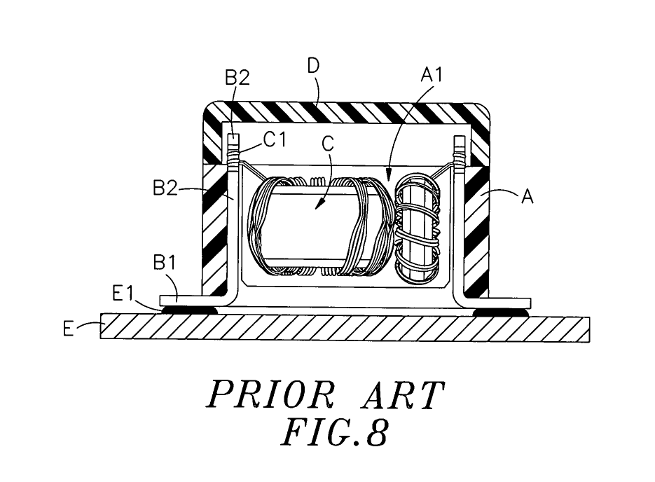

### DETAILED DESCRIPTION OF THE PREFERRED EMBODIMENT

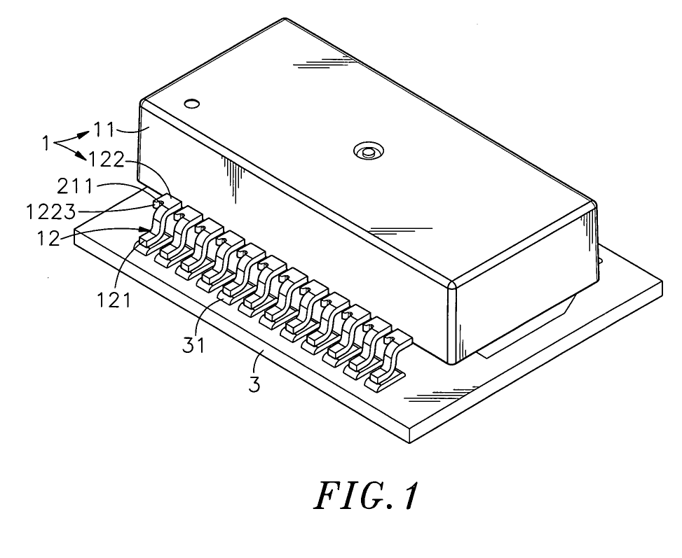

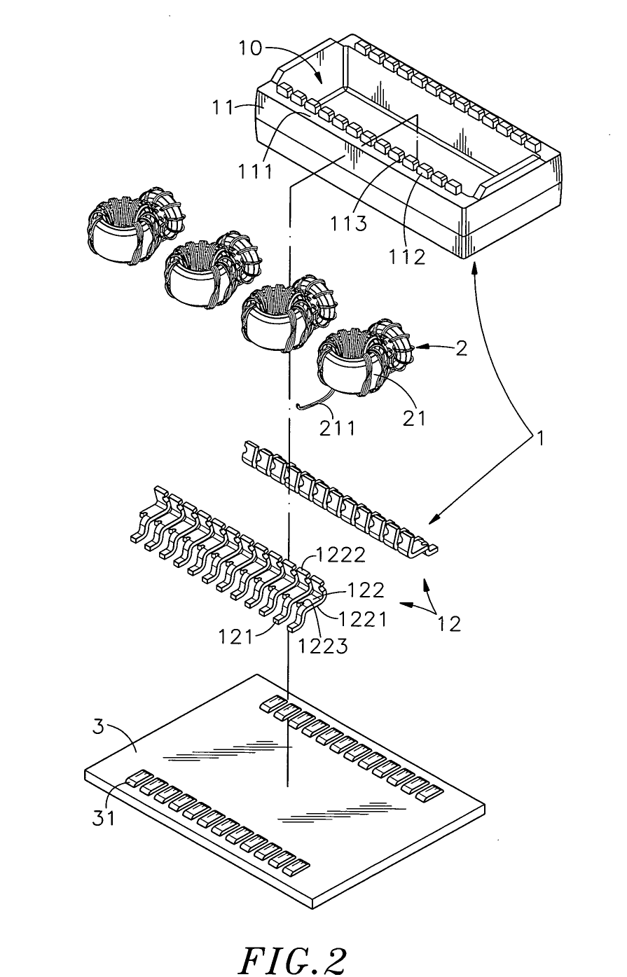

Referring to FIGS. 1 and 2, a signal filter module in accordance with a first embodiment of the present invention is shown comprising an electrically insulative housing 1 and a plurality of filter elements 2.

The electrically insulative housing 1 holds a set of metal terminals 12. Further, the electrically insulative housing 1 has an accommodation open chamber 10 opened on the bottom side thereof, two rows of protruding blocks 112 respectively protruded from the bottom edge 111 of each of the two opposite vertical sidewalls 11 thereof, and a wire groove 113 defined between each two adjacent protruding blocks 112 at the bottom edge 111 of each of the two opposite vertical sidewalls 11. The metal terminals 12 are respectively embedded in the two opposite vertical sidewalls 11 of the electrically insulative housing 1 near the associating protruding blocks 112 and wire grooves 113 for bonding to respective metal contacts 31 at a circuit board 3. Each metal terminal 12 has a base 122 partially embedded in one vertical sidewall 11 and partially suspending outside the associating vertical sidewall 11, a bonding tip 121 curved downwards and then forwards from the base 122 for bonding to one respective metal contact 31 at the circuit board 3. The base 122 has a bonding surface 1221 disposed in flush the bottom edge 111 of the associating vertical sidewall 11 and suspending outside the electrically insulative housing 1.

The filter elements 2 are formed of resistors, capacitors, or any other passive components or wave filters, each having coils 21 wound thereon. The coils 21 have respective lead ends 211 inserted through the wire grooves 113 of the electrically insulative housing 1 and bonded to the bonding surfaces 1221 of the bases 122 of the metal terminals 12.

Further, each metal terminal 12 has an interference block 1222 obliquely upwardly extended from one end of the base 122 thereof opposite to the bonding tip 121 and embedded inside the associating vertical sidewall 11 of the electrically insulative housing 1 to enhance the binding strength between the respective metal terminal 12 and the electrically insulative housing 1, avoiding disconnection of the respective metal terminal 12 from the electrically insulative housing 1 upon a sharp temperature change or accidental impact. Further, the interference block 1222 can be configured to provide a crevice or raised portion, enabling the binding strength between the respective metal terminal 12 and the electrically insulative housing 1.

Further, the base 122 of each metal terminal 12 can be configured having a width greater than the respective bonding tip 121 so that there is a width difference between the base 122 and the bonding tip 121 for the positioning of one lead end 211 of one coil 21 of one filter element 2. The bonding tip 121 has one side edge kept in flush with the corresponding side edge of the base 122. A locating notch 1223 is made on the front end of the base 122 and abutted against the other side edge of the bonding tip 121 for the positioning of the lead end 211 of the respective coil 21 so that the lead end 211 can be kept in contact with a large area of the bonding surface 1221 of the base 122, facilitating bonding. Further, the interference block 1222 of each metal terminal 12 extends obliquely upwardly from the associating base 122. Further, the metal terminals 12 are reversely embedded in the two vertical sidewalls 11 of the electrically insulative housing 1 in a staggered manner.

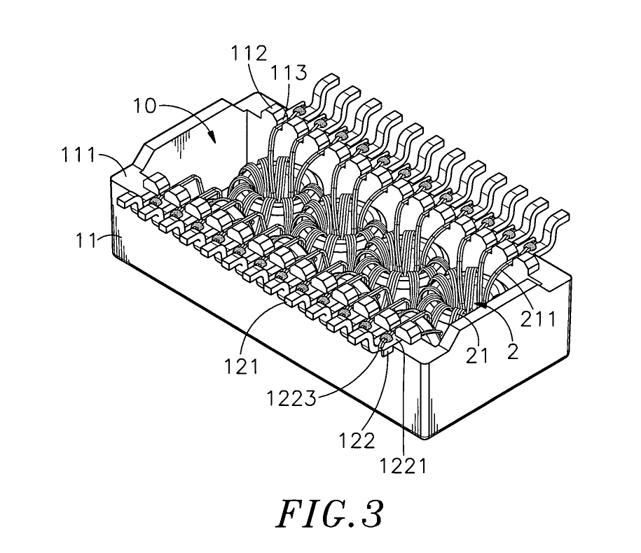

When assembling the signal filter module, the filter elements 2 are set in the accommodation open chamber 10 of the electrically insulative housing 1, and then the lead ends 211 of the coils 21 of the filter elements 2 are respectively pulled outwards and inserted through the wire grooves 113 to the outside of the electrically insulative housing 1. After insertion of the lead ends 211 of the coils 21 of the filter elements 2 through the respective wire grooves 113, the wire grooves 113 guide the lead ends 211 into contact with the bonding surfaces 1221 of the bases 122 of the metal terminals 12 for quick bonding (see FIG. 3). Thereafter, the lead ends 211 are respectively fastened to the locating notches 1223 of the metal terminals 12 and bonded to the bonding surfaces 1221 of the bases 122 of the metal terminals 12 by a soldering machine accurately.

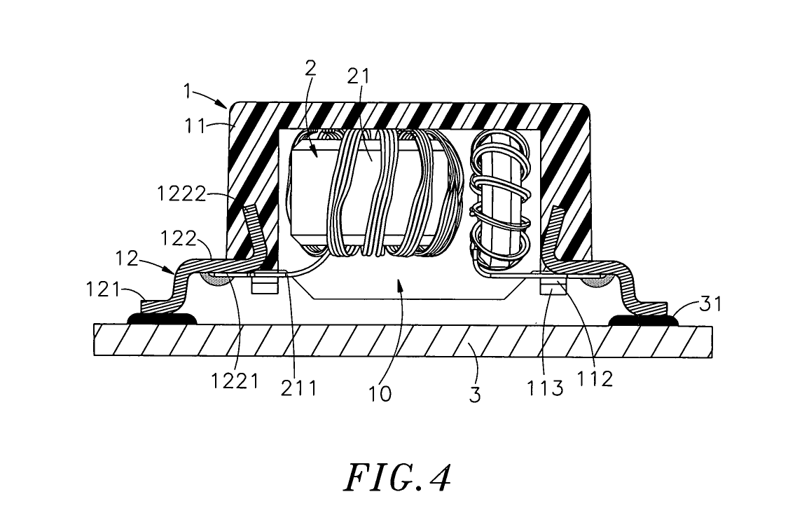

Referring to FIG. 4, during application of the signal filter module, the bonding tips 121 of the metal terminals 12 are respectively bonded to respective metal contacts 31 of a circuit board 3. The modularized design of the signal filter module simplifies the processing flow and saves much the processing time, suitable for high-yield mass production. The signal filter module is suitable for use on the main board of a signal transmission apparatus or the circuit board of any of a variety of interface card (not limited to RJ-11 or RJ-45). When an external signal is transmitted through a cable to the circuit board 3 in which the signal filter module is installed, the signal is transmitted through the metal contacts 31 of the circuit board 3 to the metal terminals 12 and then to the lead ends 211 of the coils 21 of the filter elements 2 through the bonding surfaces 1221 of the bases 122 of the metal terminals 12 for filtration by the filter elements 2 to remove noises. After filtration through the filter elements 2, the signal is transmitted from the filter elements 2 to another external circuit board (not shown).

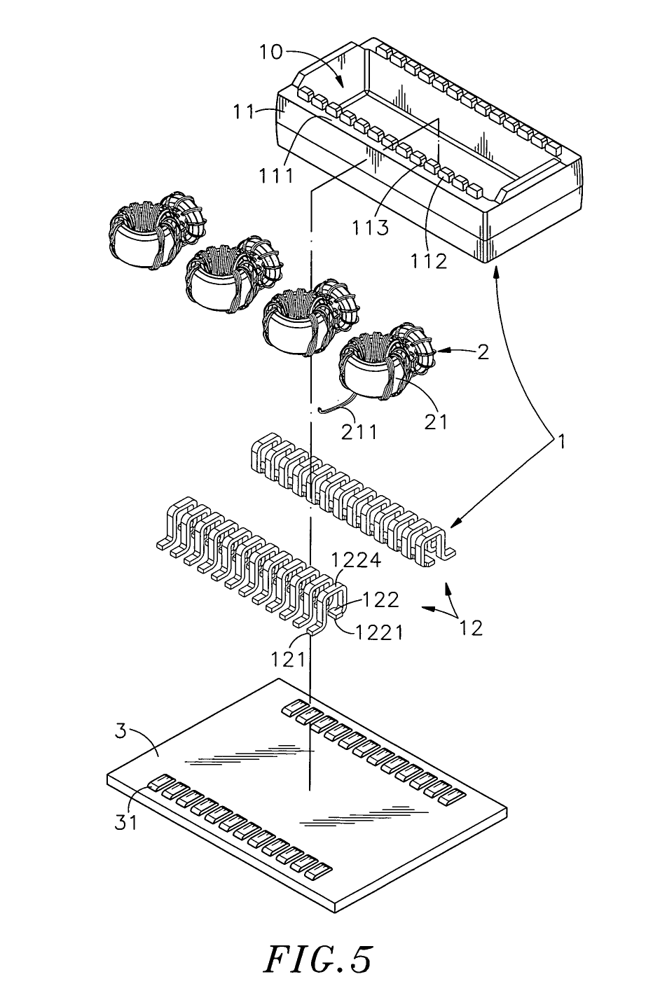

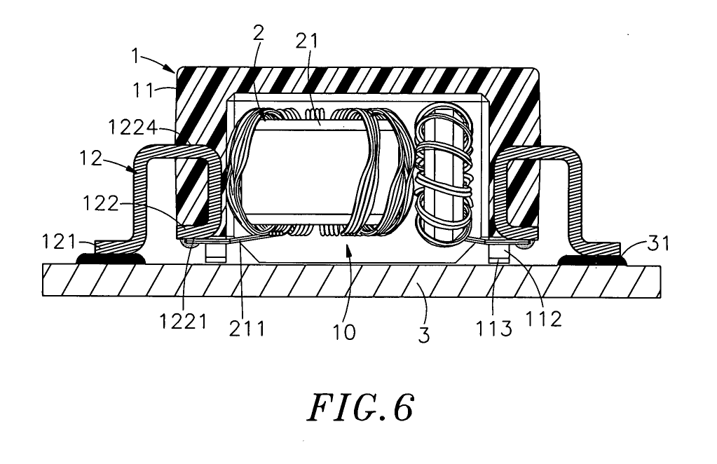

FIGS. 5 and 6 show a signal filter module in accordance with a second embodiment of the present invention. This second embodiment is substantially similar to the aforesaid first embodiment with the exception of the structure of the metal terminals 12. According to this second embodiment, each metal terminal 12 has a base 122, a bonding tip 121 for bonding to one respective metal contact 31 at a circuit board 3, and an inverted-U connection portion 1224 connected between the base 122 and the bonding tip 121 and embedded in the associating vertical sidewall 11 of the electrically insulative housing 1. The base 122 has a bonding surface 1221 disposed in flush the bottom edge 111 of the associating vertical sidewall 11 of the electrically insulative housing 1 for the bonding of one lead end 211 of one coil 21 of one filter element 2 that goes through one wire groove 113 of the electrically insulative housing 1.

As stated, each metal terminal 12 of the signal filter module has its base 122 partially embedded in one vertical sidewall 11 of the electrically insulative housing 1 to keep the bonding surface 1221 in flush with the bottom edge 111 of the respective vertical sidewall 11 for the bonding of the one lead end 211 of one coil 21 of one filter element 2 and its bonding tip 121 suspending outside the electrically insulative housing 1 for bonding to one respective metal contact 31 at a circuit board 3. Further, each metal terminal 12 can be configured having an interference block 1222 obliquely upwardly extended from one end of the base 122 thereof for fixation to the inside of one of the two opposite Vertical sidewalls 11 of the electrically insulative housing 1 to enhance the binding strength between the respective metal terminal 12 and the electrically insulative housing 1. Alternatively, each metal terminal 12 can be configured having an inverted-U connection portion 1224 connected between the base 122 and bonding tip 121 thereof for fixation to the inside of one of the two opposite vertical sidewalls 11 of the electrically insulative housing 1 to enhance the binding strength between the respective metal terminal 12 and the electrically insulative housing 1.

Further, the bonding surface 1221 of the base 122 of each metal terminal 12 and the bottom edge 111 of the associating vertical sidewall 11 of the electrically insulative housing 1 can be so arranged to provide a co-plane, facilitating bonding of one lead end 211 of one coil 21 of one filter element 2. Alternatively, the bonding surface 1221 of the base 122 of each metal terminal 12 and the bottom edge 111 of the associating vertical sidewall 11 of the electrically insulative housing 1 can be arranged in parallel but not a co-plane.

Further, the electrically insulative housing 1, the metal terminals 12 and the filter elements 2 are arranged together, forming a chip type signal filter module. The scope of the technical features of the signal filter module is that the electrically insulative housing 1 has two rows of protruding blocks 112 respectively protruded from the bottom edge 111 of each of the two opposite vertical sidewalls 11 thereof, and a wire groove 113 defined between each two adjacent protruding blocks 112 at the bottom edge 111 of each of the two opposite vertical sidewalls 11; each metal terminal 12 has a base 122 partially embedded in one of the two opposite vertical sidewalls 11 of the electrically insulative housing 1 with the bonding surface 1221 of the base 122 exposed to the outside of the bottom edge 111 of the associating vertical sidewall 11 for the bonding of one lead end 211 of one coil 21 of one filter element 2, and a bonding tip 121 suspending outside the electrically insulative housing 1 for bonding to one respective metal contact 31 at the circuit board 3; the filter elements 2 have the lead ends 211 of the coils 21 thereof extended through the wire grooves 113 of the electrically insulative housing 1 and bonded to the bonding surfaces 1221 of the bases 122 of the metal terminals 12 respectively. This arrangement diminishes terminal material consumption and facilitates bonding of the lead ends 211 of the coils 21 to the metal terminals 12 by an automatic soldering machine.

In conclusion, the invention provides a signal filter module, which has the following advantages and technical features:

1. The metal terminals 12 are directly embedded in the vertical sidewalls 11 of the electrically insulative housing 1, each having the base 122 thereof exposed to the outside of the bottom edge 111 of the associating vertical sidewall 11 for the bonding of one lead end 211 of one coil 21 of one filter element 2 and the bonding tip 121 thereof suspending outside the electrically insulative housing 1 for bonding to one respective metal contact 31 of an external circuit board 3. This design needs not to insert the base 122 of each metal terminal 12 through the front and back sides of the associating vertical sidewall 11 so that the metal terminals 12 can be relatively shortened, diminishing terminal material consumption and saving the cost.

2. The metal terminals 12 are directly embedded in the vertical sidewalls 11 of the electrically insulative housing 1 that can be configured subject to any of a variety of sizes and specifications to fit different requirements, i.e., one common specification of metal terminals 12 can be used to fit different sizes of electrically insulative housings 1.

3. The lead ends 211 of the coils 21 of the filter elements 2 are respectively inserted through the wire grooves 113 of the electrically insulative housing 1 and secured to the locating notches 1223 of the metal terminals 12 for easy bonding to the bonding surfaces 1221 of the bases 122 of the metal terminals 12 by an automatic soldering machine, lowering the defective rate and simplifying the fabrication.

4. The metal terminals 12 can be directly embedded in the vertical sidewalls 11 of the electrically insulative housing 1 by means of insert molding, simplifying the fabrication and saving the manufacturing cost.

A prototype of signal filter module has been constructed with the features of FIGS. 16. The hanging rack assembly functions smoothly to provide all of the features disclosed earlier.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A signal filter module, comprising an electrically insulative housing, a plurality of metal terminals installed in said electrically insulative housing at two opposite sides for bonding to an external circuit board, and a plurality of filter elements mounted inside said electrically insulative housing and electrically connected to said metal terminals, wherein:
said electrically insulative housing has a plurality of protruding blocks respectively protruded from a bottom edge of each of two opposite vertical sidewalls thereof and a wire groove defined between each two adjacent protruding blocks at each of said two opposite vertical sidewalls;
said metal terminals each have a base partially embedded in one of the vertical sidewalls of said electrically insulative housing and a bonding tip extended from one end of said base and suspending outside said electrically insulative housing for bonding to an external circuit board, said base having a bonding surface exposed to the outside of the bottom edge of the associating vertical sidewall of said electrically insulative housing;
said filter elements each have a plurality of coils wound thereon, each said coil having a lead end inserted through one said wire groove of said electrically insulative housing and bonded to the bonding surface of the base of one said metal terminal.

2. The signal filter module as claimed in claim 1, wherein the bonding tips of said metal terminals are configured for bonding to respective metal contacts on a circuit board set beneath said electrically insulative housing.

3. The signal filter module as claimed in claim 1, wherein said filter elements are formed of resistors, capacitors, or any other passive components or wave filters.

4. The signal filter module as claimed in claim 1, wherein each said metal terminal has an interference block obliquely upwardly extended from one end of the base thereof and embedded in said electrically insulative housing.

5. The signal filter module as claimed in claim 1, wherein each said metal terminal has an inverted-U connection portion connected between said base and said bonding tip and embedded in one said vertical sidewall of said electrically insulative housing.

6. The signal filter module as claimed in claim 1, wherein the base of each said metal terminal has a width greater than the respective bonding tip.

7. The signal filter module as claimed in claim 1, wherein each said metal terminal has a locating notch located on one end of the base thereof and abutted against one lateral side of the bonding tip thereof.

8. The signal filter module as claimed in claim 1, wherein the bonding surface of each said metal terminal is disposed in flush with the bottom edge of the associating vertical sidewall of said electrically insulative housing, showing a co-plane.

9. The signal filter module as claimed in claim 1, wherein the bonding surface of each said metal terminal is arranged in parallel to the bottom edge of the associating vertical sidewall of said electrically insulative housing such that the bonding surface of each said metal terminal and the bottom edge of the associating vertical sidewall show two different planes.
